(19) United States
(12) Patent Application Publication
(10) Pub. No.: US 2024/0194686 A1
(43) Pub. Date: Jun. 13, 2024

(54) THIN FILM TRANSISTOR AND METHOD FOR MANUFACTURING SAME, DISPLAY PANEL, AND DISPLAY DEVICE

(71) Applicant: BOE Technology Group Co., Ltd., Beijing (CN)

(72) Inventors: Nianqi YAO, Beijing (CN); Ce NING, Beijing (CN); Zhengliang LI, Beijing (CN); Hehe HU, Beijing (CN); Shuilang DONG, Beijing (CN); Lizhong WANG, Beijing (CN); Dapeng XUE, Beijing (CN); Jiayu HE, Beijing (CN); Jie HUANG, Beijing (CN); Lubin SHI, Beijing (CN); Liping LEI, Beijing (CN)

(21) Appl. No.: 17/908,652

(22) PCT Filed: Oct. 25, 2021
(86) PCT No.: PCT/CN2021/126089

§ 371 Date: Sep. 1, 2022

(30) Foreign Application Priority Data
Mar. 15, 2021 (CN) 202110276322.9

(51) Int. Cl. H01L 27/12; H01L 29/66; H01L 29/786

(52) U.S. Cl. CPC H01L 27/1225; H01L 29/66742; H01L 29/78606; H01L 29/7869

(57) ABSTRACT

Provided is a thin film transistor and a method for manufacturing thereof, a display panel, and a display device, which relates to the field of display technologies. The thin film transistor includes an active layer, source and drain electrodes, and an oxygen supplementation layer. As an orthogonal projection of the oxygen supplementation layer on the base substrate is at least partially overlapped with an orthogonal projection of a target portion of the active layer on the base substrate, oxygen introduced in forming the oxygen supplementation layer in the thin film transistor is capable of diffusing to the target portion of the active layer, such that a defect in the target portion of the active layer is reduced, and a property of the thin film transistor is greater.

### CROSS-REFERENCE TO RELATED APPLICATION

This application is a U.S. national stage of international application No. PCT/CN2021/126089, filed on Oct. 25, 2021, which claims priority to Chinese Patent Application No. 202110276322.9 filed on Mar. 15, 2021 and entitled “THIN FILM TRANSISTOR AND PREPARATION METHOD THEREOF. DISPLAY PANEL AND DISPLAY DEVICE.” and the disclosures of which are herein incorporated by reference in their entireties.

### TECHNICAL FIELD

The present disclosure relates to the field of display technologies, and in particular, relates to a thin film transistor and a method for manufacturing thereof, a display panel, and a display device.

### BACKGROUND

A thin film transistor (TFT) generally includes a gate electrode, a gate insulation layer, an active layer, and a source-drain layer that are sequentially disposed on a base substrate. The source-drain layer includes a source electrode and a drain electrode that are connected to the active layer, and the source electrode and the drain electrode are formed by etching a metal material by an etchant.

### SUMMARY

Embodiments of the present disclosure provide a thin film transistor and a method for manufacturing thereof, a display panel, and a display device. The technical solutions are as follows.

According to some embodiments of the present disclosure, a thin film transistor is provided. The thin film transistor includes:
an active layer disposed on a side of a base substrate;
source and drain electrodes disposed on a side, distal from the base substrate, of the active layer; and
an oxygen supplementation layer disposed on the side, distal from the base substrate, of the active layer and containing a metal oxide, wherein an orthogonal projection of the oxygen supplementation layer on the base substrate is at least partially overlapped with an orthogonal projection of a target portion of the active layer on the base substrate, and the orthogonal projection of the target portion on the base substrate is not overlapped with orthogonal projections of the source and drain electrodes on the base substrate.

In some embodiments, the orthogonal projection of the oxygen supplementation layer on the base substrate covers the orthogonal projection of the target portion on the base substrate.

In some embodiments, the thin film transistor further includes: a first gate electrode, a first insulation layer, and a second insulation layer: wherein

the first gate electrode, the first insulation layer, the active layer, the source and drain electrodes, the second insulation layer, and the oxygen supplementation layer are sequentially laminated in a direction away from the base substrate.

In some embodiments, the thin film transistor further includes: a second gate electrode, wherein

the second gate electrode is disposed on a side, distal from the base substrate, of the oxygen supplementation layer, and an orthogonal projection of the second gate electrode on the base substrate is at least partially overlapped with the orthogonal projection of the target portion on the base substrate.

In some embodiments, the thin film transistor further includes: at least one of a first buffer layer and a second buffer layer: wherein
the first buffer layer is disposed on a side, distal from the oxygen supplementation layer, of the second gate electrode: and
the second buffer layer is disposed between the second gate electrode and the oxygen supplementation layer.

In some embodiments, the thin film transistor further includes: a third insulation layer and a connection electrode: wherein
the third insulation layer is disposed on a side, distal from the base substrate, of the second gate electrode, the connection electrode is disposed on a side, distal from the base substrate, of the third insulation layer, and
the second gate electrode is electrically connected to the source and drain electrodes or the first gate electrode by the connection electrode.

In some embodiments, the thin film transistor further includes: a first gate electrode, a first insulation layer, and a second insulation layer: wherein

the active layer, the first insulation layer, the oxygen supplementation layer, the first gate electrode, the second insulation layer, and the source and drain electrodes are sequentially laminated in a direction away from the base substrate.

In some embodiments, the thin film transistor further includes: a shielding layer and a third insulation layer: wherein
the shielding layer is disposed on a side, proximal to the base substrate, of the active layer, the third insulation layer is disposed between the shielding layer and the active layer, and
an orthogonal projection of the shielding layer on the base substrate covers an orthogonal projection of the active layer on the base substrate.

In some embodiments, the thin film transistor further includes: at least one of a first buffer layer and a second buffer layer: wherein
the first buffer layer is disposed on a side, distal from the oxygen supplementation layer, of the first gate electrode: and
the second buffer layer is disposed between the first gate electrode and the oxygen supplementation layer.

In some embodiments, a material of the active layer includes at least one of: an indium-gallium-zinc oxide, an indium-gallium-zinc-tin oxide, an indium-tin oxide, an indium-zinc oxide, and an indium-tin-zinc oxide; and

a material of the oxygen supplementation layer includes at least one of: an indium-gallium-zinc oxide, an indium-gallium-zinc-tin oxide, an indium-tin oxide, an indium-zinc oxide, an indium-tin-zinc oxide, a molybdenum oxide, an aluminum oxide, a copper oxide, an indium oxide, a tin oxide, a zinc oxide, and a nickel oxide.

According to some embodiments of the present disclosure, a method for manufacturing a thin film transistor is provided. The method includes:
forming an active layer, source and drain electrodes, and an oxygen supplementation layer on a side of the base substrate: wherein
the source and drain electrodes are disposed on a side, distal from the base substrate, of the active layer: and
the oxygen supplementation layer is disposed on the side, distal from the base substrate, of the active layer, and contains a metal oxide, an orthogonal projection of the oxygen supplementation layer on the base substrate is at least partially overlapped with an orthogonal projection of a target portion of the active layer on the base substrate, and the orthogonal projection of the target portion on the base substrate is not overlapped with orthogonal projections of the source and drain electrodes on the base substrate.

In some embodiments, forming the oxygen supplementation layer on the side of the base substrate includes:
forming a metal oxide thin film on the side, distal from the base substrate, of the active layer by introducing oxygen into a reaction chamber in depositing a metal material on the side of the base substrate: and
forming the oxygen supplementation layer by patterning the metal oxide thin film;
wherein the oxygen is diffusible to the target portion in introducing the oxygen into the reaction chamber.

According to some embodiments of the present disclosure, a display panel is provided. The display panel includes: a base substrate, and the thin film transistor according to above embodiments: wherein the thin film transistor is disposed on the base substrate.

According to some embodiments of the present disclosure, a display device is provided. The display device includes: a power supply, and the display panel according to above embodiments: wherein

the power supply is configured to supply power to the display panel.

### BRIEF DESCRIPTION OF THE DRAWINGS

For clearer descriptions of the technical solutions in the embodiments of the present disclosure, the following briefly introduces the accompanying drawings required for describing the embodiments. Apparently, the accompanying drawings in the following description show merely some embodiments of the present disclosure, and a person of ordinary skill in the art can still derive other drawings from these accompanying drawings without creative efforts.

FIG. 1 is a schematic diagram of a relationship of a current and a voltage according to some embodiments of the present disclosure:

FIG. 2 is a schematic diagram of another relationship of a current and a voltage according to some embodiments of the present disclosure:

FIG. 3 is a schematic structural diagram of a thin film transistor according to some embodiments of the present disclosure:

FIG. 4 is a schematic structural diagram of another thin film transistor according to some embodiments of the present disclosure:

FIG. 5 is a schematic structural diagram of another thin film transistor according to some embodiments of the present disclosure:

FIG. 6 is a schematic structural diagram of another thin film transistor according to some embodiments of the present disclosure:

FIG. 7 is a schematic structural diagram of another thin film transistor according to some embodiments of the present disclosure:

FIG. 8 is a schematic structural diagram of another thin film transistor according to some embodiments of the present disclosure:

FIG. 9 is a schematic structural diagram of another thin film transistor according to some embodiments of the present disclosure;

FIG. 10 is a schematic structural diagram of another thin film transistor according to some embodiments of the present disclosure:

FIG. 11 is a schematic structural diagram of another thin film transistor according to some embodiments of the present disclosure:

FIG. 12 is a schematic structural diagram of another thin film transistor according to some embodiments of the present disclosure:

FIG. 13 is a schematic structural diagram of another thin film transistor according to some embodiments of the present disclosure;

FIG. 14 is a schematic structural diagram of another thin film transistor according to some embodiments of the present disclosure:

FIG. 15 is a flowchart of a method for manufacturing a thin film transistor according to some embodiments of the present disclosure:

FIG. 16 is a flowchart of another method for manufacturing a thin film transistor according to some embodiments of the present disclosure:

FIG. 17 is a schematic diagram of forming a first gate electrode according to some embodiments of the present disclosure;

FIG. 18 is a schematic diagram of forming a first insulation layer according to some embodiments of the present disclosure;

FIG. 19 is a schematic diagram of forming an active layer according to some embodiments of the present disclosure:

FIG. 20 is a schematic diagram of forming source and drain electrodes and a second insulation layer according to some embodiments of the present disclosure;

FIG. 21 is a schematic structural diagram of a display panel according to some embodiments of the present disclosure:

FIG. 22 is a schematic structural diagram of another display panel according to some embodiments of the present disclosure; and

FIG. 23 is a schematic structural diagram of a display device according to some embodiments of the present disclosure.

### DETAILED DESCRIPTION

For clearer descriptions of the objectives, technical solutions, and advantages in the present disclosure, the embodiments of the present disclosure are described in detail hereinafter in combination with the accompanying drawings.

A mobility and refresh rate of a conventional amorphous silicon (a-Si) thin film transistor (TFT) (a material of an active layer is a-Si) are less, and thus are difficult to meet requirements of a larger-sized television product. A metal oxide TFT (a material of an active layer is a metal oxide) has advantages such as, a greater mobility, uniform device properties, suitable for mass production, a lower manufacturing temperature, suitable for flexible display and transparent display, and the like. Thus, the metal oxide is a most potential material to replace a-Si as a material of the active layer of the TFT.

The metal oxide TFT is a new TFT, and is applicable to a liquid crystal display (LCD), an organic light-emitting diode (OLED) display, an X-ray transducer, a mini light-emitting diode (mini LED) display, a quantum dot light emitting diodes (QLED) display, a low temperature polycrystalline oxide (LTPO), and the like.

The metal oxide TFT is disposed in an array substrate when applied in a display panel. The array substrate is a part in the display panel, and is configured to control the display panel. The display panel includes other parts according to different types of the display panel. For example, in the case that the display panel is a liquid crystal display panel, the liquid crystal display panel further includes a liquid crystal layer and a color film substrate. For example, in the case that the display panel is an organic light-emitting diode display panel, the organic light-emitting diode display panel further includes an organic light-emitting diode.

An existing metal oxide TFT is sensitive, a threshold voltage is negatively biased, and a positive bias temperature stress (PBTS) of the metal oxide TFT is unstable. In addition, the negative bias temperature illumination stress (NBTIS) of the metal oxide TFT is affected upon lighting, such that a property of the metal oxide TFT is poor.

Nowadays, a number of masks required to manufacturing the metal oxide TFT is less, such that manufacturing processes are less, the production cost is saved, and the throughput is increased. However, a side, distal from a base substrate, of the active layer is prone to an effect of an etchant (an etchant for etching the metal material to form a source electrode and a drain electrode) to generate defects, and thus, it is necessary to supplement the oxygen to the active layer to reduce the defects in the active layer.

It is noted that, the defects in the side, distal from the base substrate, of the active layer causes a poor switching property of the metal oxide TFT. The switching property of the metal oxide TFT is measured by a difference value between a current in an open state and a current in a closed state. Where the difference value between the current in the open state and the current in the closed state is less, the switching property of the metal oxide TFT is poor. Where the difference value between the current in the open state and the current in the closed state is greater, the switching property of the metal oxide TFT is great.

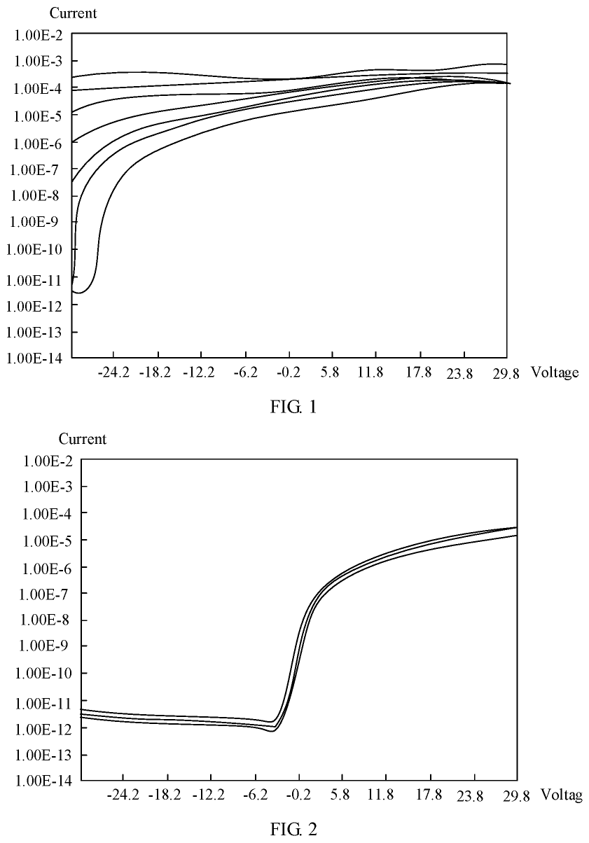

Referring to FIG. 1, the side, distal from the base substrate, of the active layer contains defects, and an oxygen supplementation is not performed on the side, distal from the base substrate, of the active layer. In the case that the metal oxide TFT is in the closed state (for example, an applying voltage is less than a threshold voltage), a current is present in each portion of the active layer, and difference values of currents in different regions are greater (for example, latitude coordinates of each curve in the drawing represent currents of one region at different voltages). Thus, the difference value of the metal oxide TFT between the current in the open state and the current in the closed state is less, and the switching property of the metal oxide TFT is poor.

Referring to FIG. 2, the side, distal from the base substrate, of the active layer contains defects, and an oxygen supplementation is performed on the side, distal from the base substrate, of the active layer. In the case that the metal oxide TFT is in the closed state (for example, an applying voltage is less than a threshold voltage), a current in each portion of the active layer is less (such as, 0). In the case that the metal oxide TFT is in the open state (for example, an applying voltage is increased to the threshold voltage), a current in each portion of the active layer is increased and tends to be stable. Thus, the difference value of the metal oxide TFT between the current in the open state and the current in the closed state is greater, difference values of currents in different regions at the same voltage are less, and the switching property of the metal oxide TFT is greater.

In the embodiments of the present disclosure, by adding an oxygen supplementation layer in the metal oxide TFT, oxygen introduced in manufacturing the oxygen supplementation layer is capable of diffusing to the active layer, such that a stability of the PBTS of the metal oxide TFT is improved, and the property of the metal oxide TFT is ensured.

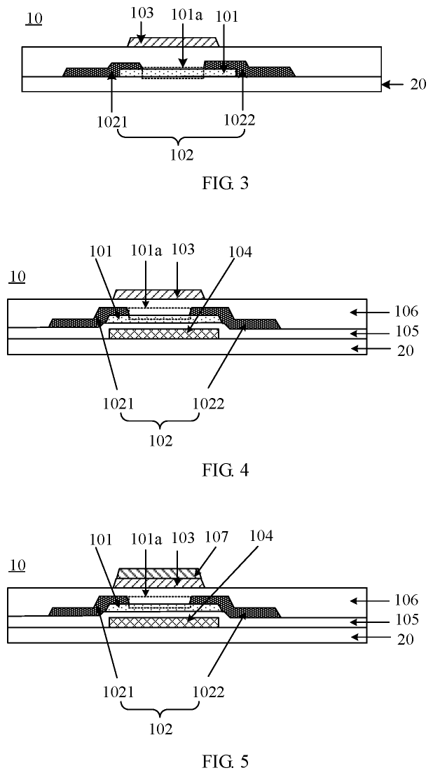

FIG. 3 is a schematic structural diagram of a thin film transistor according to some embodiments of the present disclosure. Referring to FIG. 3, the thin film transistor 10 includes: an active layer 101, source and drain electrodes 102, and an oxygen supplementation layer 103 that are disposed on a base substrate 20. The source and drain electrodes 102 are disposed on a side, distal from the base substrate 20, of the active layer 101, and the oxygen supplementation layer 103 is disposed on the side, distal from the base substrate 20, of the active layer 101 and contains a metal oxide.

An orthogonal projection of the oxygen supplementation layer 103 on the base substrate 20 is at least partially overlapped with an orthogonal projection of a target portion 101a of the active layer 101 on the base substrate 20, and the orthogonal projection of the target portion 101a on the base substrate 20 is not overlapped with orthogonal projections of the source and drain electrodes 102 on the base substrate 20.

As the orthogonal projection of the target portion 101a of the active layer 101 on the base substrate 20 is not overlapped with the orthogonal projections of the source and drain electrodes 102 on the base substrate 20, compared with other portions of the active layer 101, the target portion 101a of the active layer 101 is prone to an effect of an etchant in forming the source and drain electrodes 102 by etching a metal material by the etchant, so as to generate defects. Thus, it is necessary to perform the oxygen supplementation on the target portion 101a to improve the defects of oxygen vacancies in the target portion 101a of the active layer 101, so as to ensure the property of the thin film transistor.

In the embodiments of the present disclosure, film layers of the thin film transistor are formed in a reaction chamber. As the oxygen supplementation layer 103 includes the metal oxide, the oxygen is introduced into the reaction chamber in depositing the metal material when the oxygen supplementation layer 103 is formed. In addition, as the oxygen supplementation layer 103 is disposed on the side, distal from the base substrate 20, of the active layer 101, the active layer 101 is formed prior to the oxygen supplementation layer 103. In the case that the orthogonal projection of the oxygen supplementation layer 103 on the base substrate 20 is at least partially overlapped with the orthogonal projection of the target portion 101a of the active layer 101 on the base substrate 20, oxygen introduced into the reaction chamber in forming the oxygen supplementation layer 103 is capable of diffusing to the target portion 101a of the active layer 101, such that the defects of oxygen vacancies in the target portion 101a of the active layer 101 is reduced, and the property of the thin film transistor 10 is greater.

In summary, a thin film transistor is provided in the embodiments of the present disclosure. The thin film transistor includes an active layer, source and drain electrodes, and an oxygen supplementation layer. As an orthogonal projection of the oxygen supplementation layer on the base substrate is at least partially overlapped with an orthogonal projection of a target portion of the active layer on the base substrate, oxygen introduced in forming the oxygen supplementation layer in the thin film transistor is capable of diffusing to the target portion of the active layer, such that a defect in the target portion of the active layer is reduced, and the property of the thin film transistor is greater.

In the embodiments of the present disclosure, the oxygen supplementation layer 103 is formed from the metal oxide material. For example, a material of the oxygen supplementation layer 103 includes at least one of: an indium-gallium-zinc oxide (IGZO), an indium-gallium-zinc-tin oxide (IGZTO), an indium-tin oxide (ITO), an indium-zinc oxide (IZO), an indium-tin-zinc oxide (ITZO), a molybdenum oxide (MoO), an aluminum oxide (AlO), a copper oxide (CuO), an indium oxide (InO), a tin oxide (SnO), a zinc oxide (ZnO), and a nickel oxide (NiO).

In the embodiments of the present disclosure, the active layer 101 is formed from the metal oxide material. For example, a material of the active layer 101 includes one or more metal oxides. The material of the active layer 101 includes at least one of IGZO, IGZTO, ITO, IZO and ITZO.

In addition, an oxygen content of the active layer 101 is controlled by a content of the oxygen introduced into the reaction chamber in forming the active layer 101. The oxygen content of the active layer 101 is positively correlated with the content of the oxygen introduced in forming the active layer 101. That is, the greater the content of the oxygen introduced in forming, the greater the oxygen content of the active layer 101. The less the content of the oxygen introduced in forming, the less the oxygen content of the active layer 101. The structure of the active layer 101 is a crystalline state or an amorphous state, and the structure of the active layer 101 is not limited in the embodiments of the present disclosure.

In some embodiments, the active layer 101 includes a layer of metal oxide, or a plurality of layers of metal oxides. In the case that the active layer 101 includes a plurality of layers of metal oxides, materials of the plurality of layers of metal oxides are different. In addition, a thickness of the active layer 101 ranges from 20 nm to 150 nm.

In the embodiments of the present disclosure, referring to FIG. 3, the source and drain electrodes 102 include a source electrode 1021 and a drain electrode 1022 that are spaced, and the source electrode 1021 and the drain electrode 1022 are connected to the active layer 101. The orthogonal projection of the target portion 101a on the base substrate 20 being not overlapped with the orthogonal projections of the source and drain electrodes 102 on the base substrate 20 means that the orthogonal projection of the target portion 101a on the base substrate 20 is not overlapped with an orthogonal projection of the source electrode 1021 on the base substrate 20 and an orthogonal projection of the drain electrode 1022 on the base substrate 20.

In some embodiments, the source and drain electrodes 102 are formed from the metal oxide material. For example, materials of the source and drain electrodes 102 include a pure metal or an alloy. The materials of the source and drain electrodes 102 include at least one of: aluminum (Al), molybdenum (Mo), aluminum neodymium (AlNd), a molybdenum alloy (MTD), copper (Cu), and a molybdenum neodymium (MoNd). In addition, thicknesses of the source and drain electrodes 102 range from 10 nm to 700 nm.

In some embodiments, the source and drain electrodes 102 include a layer of metal oxide, or a plurality of layers of metal oxides. In the case that the source and drain electrodes 102 include a plurality of layers of metal oxides, materials of the plurality of layers of metal oxides are different.

In the embodiments of the present disclosure, the orthogonal projection of the oxygen supplementation layer 103 on the base substrate 20 covers the orthogonal projection of the target portion 101a on the base substrate 20. That is, the orthogonal projection of the target portion 101a on the base substrate 20 falls within the orthogonal projection of the oxygen supplementation layer 103 on the base substrate 20.

As the orthogonal projection of the oxygen supplementation layer 103 on the base substrate 20 covers the orthogonal projection of the target portion 101a on the base substrate 20, the oxygen introduced into the reaction chamber in forming the oxygen supplementation layer 103 is capable of diffusing to a larger region of the target portion 101a, such that the defects in the target portion 101a is reduced, and the property of the thin film transistor 10 is ensured.

In some embodiments, referring to FIG. 4, the thin film transistor 10) further includes: a first gate electrode 104, a first insulation layer 105, and a second insulation layer 106. The first gate electrode 104, the first insulation layer 105, the active layer 101, the source and drain electrodes 102, the second insulation layer 106, and the oxygen supplementation layer 103 are sequentially laminated in a direction away from the base substrate 20. That is, the first insulation layer 105 is disposed between the first gate electrode 104 and the active layer 101, and is configured to insulate the first gate electrode 104 from the active layer 101. The second insulation layer 106 is disposed between the source and drain electrodes 102 and the oxygen supplementation layer 103, and is configured to insulate the source and drain electrodes 102 from the oxygen supplementation layer 103.

In some embodiments, the first gate electrode 104 is formed from a metal material. For example, a material of the first gate electrode 104 includes a pure metal or an alloy. The material of the first gate electrode 104 includes at least one of: aluminum (Al), molybdenum (Mo), aluminum neodymium (AlNd), a molybdenum alloy (MTD), copper (Cu), a molybdenum neodymium (MoNd), and titanium (Ti). In addition, a thickness of the first gate electrode 104 ranges from 10 nm to 700 nm.

The first insulation layer 105 is further referred to as a gate insulator (GI) layer. A material of the first insulation layer 105 includes at least one of: a silicon oxide (SiO), a silicon oxynitride (SiON), and a silicon nitride (SiN). A thickness of the first insulation layer 105 ranges from 10 nm to 700 nm.

The second insulation layer 106 is further referred to as a first passivation layer (PVX). A material of the second insulation layer 106 includes at least one of: SiO, SiON, and SiN. A thickness of the second insulation layer 106 ranges from 10 nm to 700 nm.

In the embodiments of the present disclosure, as the first gate electrode 104 is disposed on the side, proximal to the base substrate 20, of the active layer 101, the first gate electrode 104 is configured to blocking light from a side, proximal to the base substrate 20, of the first gate electrode 104, and reduce an effect of the light on the target portion 101a of the active layer 101 disposed on a side, distal from the base substrate 20, of the first gate electrode 104, such that the property of the thin film transistor is greater.

FIG. 5 is a schematic structural diagram of another thin film transistor according to some embodiments of the present disclosure. Referring to FIG. 5, the thin film transistor 10 further includes: a second gate electrode 107. The second gate electrode 107 is disposed on a side, distal from the base substrate 20, of the oxygen supplementation layer 103, and an orthogonal projection of the second gate electrode 107 on the base substrate 20 are at least partially overlapped with the orthogonal projection of the target portion 101a on the base substrate 20.

In the embodiments of the present disclosure, the second gate electrode 107 is formed from the metal oxide material. In some embodiments, a material of the second gate electrode 107 includes a pure metal or an alloy. In some embodiments, the material of the second gate electrode 107 includes at least one of: Al, Mo, AlNd, MTD, Cu. MoNd and Ti. The material of the second gate electrode 107 is the same as the material of the first gate electrode 104, or different from the material of the first gate electrode 104, which is not limited in the embodiments of the present disclosure. In addition, as the second gate electrode 107 is formed from the metal oxide material, the second gate electrode 107 is configured to conduct electricity (for example, transmitting signals). In addition, a thickness of the second gate electrode 107 ranges from 10 nm to 700 nm.

As the material of the second gate electrode 107 includes the metal material, light is not transmitted through the second gate electrode 107. By disposing the second gate electrode 107, light from a side, distal from the base substrate 20, of the second gate electrode 107 is blocked, and an effect of the light on the target portion 101a of the active layer 101 disposed on a side, proximal to the base substrate 20, of the second gate electrode 107 is reduced, such that the property of the thin film transistor is greater.

In the embodiments of the present disclosure, the thin film transistor 10 further includes: at least one of a first buffer layer 108 and a second buffer layer 109. The first buffer layer 108 is disposed on a side, distal from the oxygen supplementation layer 103, of the second gate electrode 107, and the second buffer layer 109 is disposed between the second gate electrode 107 and the oxygen supplementation layer 103.

Disposing the first buffer layer 108 or the second buffer layer 109 is capable of preventing other film layers from corroding the second gate electrode 107, such that a quality of the second gate electrode 107 is ensured, and the property of the thin film transistor is ensured.

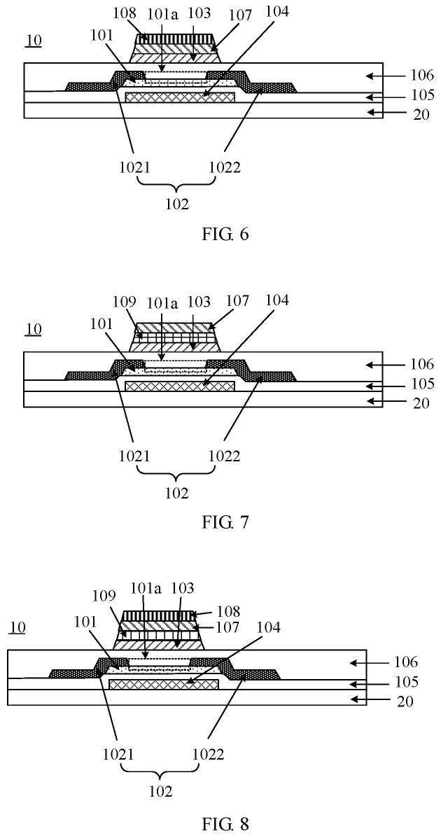

In some embodiments, referring to FIG. 6, the thin film transistor 10 merely includes the first buffer layer 108. In some embodiments, referring to FIG. 7, the thin film transistor 10) merely includes the second buffer layer 109. In some embodiments, referring to FIG. 8, the thin film transistor 10 includes the first buffer layer 108 and the second buffer layer 109.

In the embodiments of the present disclosure, the oxygen supplementation layer 103, the second gate electrode 107, the first buffer layer 108, and the second buffer layer 109 are formed by the same mask. The first buffer layer 108 and the second buffer layer 109 are formed from insulation materials. Both a thickness of the first buffer layer 108 and a thickness of the second buffer layer 109 range from 10 nm to 100 nm.

In some embodiments, a sheet resistance of the oxygen supplementation layer 103 is greater than a sheet resistance of the first buffer layer 108 and a sheet resistance of the second buffer layer 109. In addition, both the sheet resistance of the first buffer layer 108 and the sheet resistance of the second buffer layer 109 are greater than a sheet resistance of the second gate electrode 107.

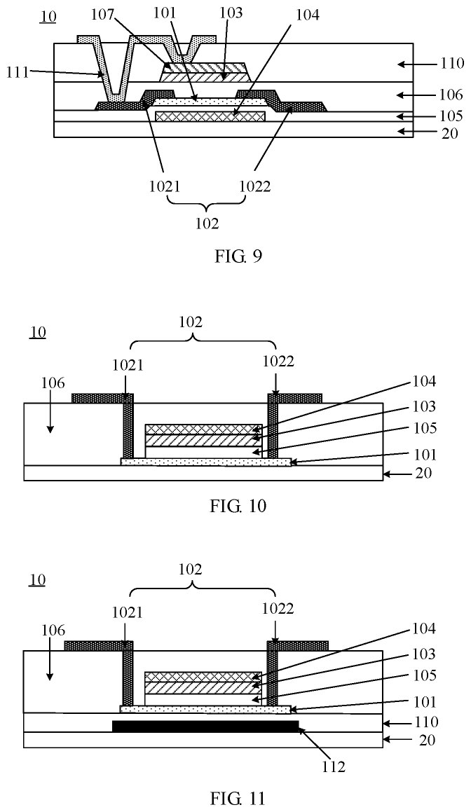

FIG. 9 is a schematic structural diagram of another thin film transistor according to some embodiments of the present disclosure. Referring to FIG. 9, the thin film transistor 10 further includes: a third insulation layer 110 and a connection electrode 111.

In some embodiments, the third insulation layer 110 is disposed on a side, distal from the base substrate 20, of the second gate electrode 107, and the connection electrode 111 is disposed on a side, distal from the base substrate 20, of the third insulation layer 110. The second gate electrode 107 is electrically connected to the source and drain electrodes 102 or the first gate electrode 104 by the connection electrode 111. The connection electrode 111 is formed from a transparent material, such as, ITO.

In some embodiments, the second gate electrode 107 is connected to the first gate electrode 104, the source electrode 1021, or the drain electrode 1022. Where the second gate electrode 107 is connected to the first gate electrode 104, a signal in the second gate electrode 107 is the same as a signal in the first gate electrode 104. Where the second gate electrode 107 is connected to the source electrode 1021, a signal in the second gate electrode 107 is the same as a signal in the source electrode 1021. Where the second gate electrode 107 is connected to the drain electrode 1022, a signal in the second gate electrode 107 is the same as a signal in the drain electrode 1022.

In some embodiments, the second gate electrode 107 is not connected to the first gate electrode 104, the source 1021, and the drain electrode 1022. In this case, a signal in the second gate electrode 107 is different from a signal in the first gate electrode 104, a signal in the source 1021, and a signal in the drain electrode 1022. In some embodiments, the second gate electrode 107 does not transmit the signal, and merely functions as blocking light.

In some embodiments, referring to FIG. 9, the thin film transistor 10 is not provided with the first buffer layer 108 and the second buffer layer 109, one end of the connection electrode 111 is connected to the second gate electrode 107 via a first via hole in the third insulation layer 110, and the other end of the connection electrode 111 is connected to the source electrode 1021 via a second via hole in the second insulation layer 106 and a third via hole in the third insulation layer 110. An orthogonal projection of the second via hole on the base substrate 20 is at least partially overlapped with an orthogonal projection of the third via hole on the base substrate 20.

Where the thin film transistor 10 is not provided with the first buffer layer 108 and the second buffer layer 109, the second gate electrode 107 is electrically connected to the source and drain electrodes 102 or the first gate electrode 104 by the connection electrode 111. Where the thin film transistor 10 is provided with the second buffer layer 109 and is not provided with the first buffer layer 108, connection between the connection electrode 111 and the second gate electrode 107 is referred to the connection without the first buffer layer 108 and the second buffer layer 109.

Where the thin film transistor 10 is provided with the first buffer layer 108, one end of the connection electrode 111 is connected to the second gate electrode 107 via a fourth via hole in the first buffer layer 108 and the first via hole in the third insulation layer 110, and the other end of the connection electrode 111 is connected to the source electrode 1021 via the second via hole in the second insulation layer 106 and the third via hole in the third insulation layer 110. An orthogonal projection of the fourth via hole on the base substrate 20 is at least partially overlapped with an orthogonal projection of the first via hole on the base substrate 20.

In the embodiments of the present disclosure, the third insulation layer 110 is also referred to as a second passivation layer. A material of the third insulation layer 110 includes at least one of: a silicon dioxide (SiO₂) and a silicon oxynitride (SiON). A thickness of the third insulation layer 110 ranges from 10 nm to 700 nm.

In some embodiments, referring to FIG. 10, the thin film transistor 10 further includes: the first gate electrode 104, the first insulation layer 105, and the second insulation layer 106. The active layer 101, the first insulation layer 105, the oxygen supplementation layer 103, the first gate electrode 104, the second insulation layer 106, and the source and drain electrodes 102 are sequentially laminated in a direction away from the base substrate 20. That is, the first insulation layer 105 is disposed between the active layer 101 and the oxygen supplementation layer 103, and is configured to insulate the active layer 101 and the oxygen supplementation layer 103. The second insulation layer 106 is disposed between the first gate electrode 104 and the source and drain electrodes 102, and is configured to insulate the first gate electrode 104 and the source and drain electrodes 102.

In the embodiments of the present disclosure, as the first gate electrode 104 is disposed on a side, distal from the base substrate 20, of the active layer 101, the first gate electrode 104 is configured to blocking light from a side, distal from the base substrate 20, of the first gate electrode 104, and reduce an effect of the light on the target portion 101a of the active layer 101 disposed on a side, proximal to the base substrate 20, of the first gate electrode 104, such that the property of the thin film transistor is greater.

In some embodiments, the first gate electrode 104 is formed from the metal material. In some embodiments, a material of the first gate electrode 104 includes a pure metal or an alloy. In some embodiments, the material of the first gate electrode 104 includes at least one of: Al, molybdenum (Mo), AlNd, MTD, Cu, MoNd and Ti. In addition, a thickness of the first gate electrode 104 ranges from 10 nm to 700 nm.

The first insulation layer 105 is further referred to as a gate insulator layer. A material of the first insulation layer 105 includes at least one of: SiO, SiON, and SiN. A thickness of the first insulation layer 105 ranges from 10 nm to 700 nm.

The second insulation layer 106 is further referred to as a first passivation layer. A material of the second insulation layer 106 includes at least one of: SiO, SiON, and SiN. A thickness of the second insulation layer 106 ranges from 10 nm to 700 nm.

FIG. 11 is a schematic structural diagram of another thin film transistor according to some embodiments of the present disclosure. Referring to FIG. 11, the thin film transistor 10) further includes: a shielding layer 112 and the third insulation layer 110. The shielding layer 112 is disposed on a side, proximal to the base substrate 20, of the active layer 101, the third insulation layer 110 is disposed between the shielding layer 112 and the active layer 101, and an orthogonal projection of the shielding layer 112 on the base substrate 20 covers an orthogonal projection of the active layer 101 on the base substrate 20.

In the embodiments of the present disclosure, the shielding layer 112 is formed from the metal material. In some embodiments, a material of the shielding layer 112 includes a pure metal or an alloy. In some embodiments, the material of the shielding layer 112 includes at least one of: Al, Mo, AlNd, MTD, Cu, MoNd and Ti.

As the material of the shielding layer 112 includes the metal material, light is not transmitted through the shielding layer 112. By disposing the shielding layer 112, light from a side, proximal to the base substrate 20, of the shielding layer 112 is blocked, and an effect of the light on the target portion 101a of the active layer 101 disposed on a side, distal from the base substrate 20, of the shielding layer 112 is reduced, such that the property of the thin film transistor is greater.

In the embodiments of the present disclosure, the shielding layer 112 is also formed from the metal material or other light shielding material. Where the shielding layer 112 is formed from the metal material, the shielding layer 112 is configured to conduct electricity (for example, transmitting signals). Thus, the shielding layer 112 is connected to the source and drain electrodes 102 or the first gate electrode 104 by the connection electrode. In some embodiments, the shielding layer 112 is connected to the first gate electrode 104, the source electrode 1021, or the drain electrode 1022. Where the shielding layer 112 is connected to the first gate electrode 104, a signal in the shielding layer 112 is the same as a signal in the first gate electrode 104. Where the shielding layer 112 is connected to the source electrode 1021, a signal in the shielding layer 112 is the same as a signal in the source electrode 1021. Where the shielding layer 112 is connected to the drain electrode 1022, a signal in the shielding layer 112 is the same as a signal in the drain electrode 1022.

In some embodiments, the shielding layer 112 is not connected to the first gate electrode 104, the source electrode 1021, and the drain electrode 1022. In this case, the shielding layer 112 merely functions as blocking light.

In the embodiments of the present disclosure, the thin film transistor 10 further includes: at least one of a first buffer layer 108 and a second buffer layer 109. The first buffer layer 108 is disposed on a side, distal from the oxygen supplementation layer 103, of the second gate electrode 107, and the second buffer layer 109 is disposed between the second gate electrode 107 and the oxygen supplementation layer 103.

Disposing the first buffer layer 108 or the second buffer layer 109 is capable of preventing other film layers from corroding the second gate electrode 107, such that a quality of the second gate electrode 107 is ensured, and the property of the thin film transistor is ensured.

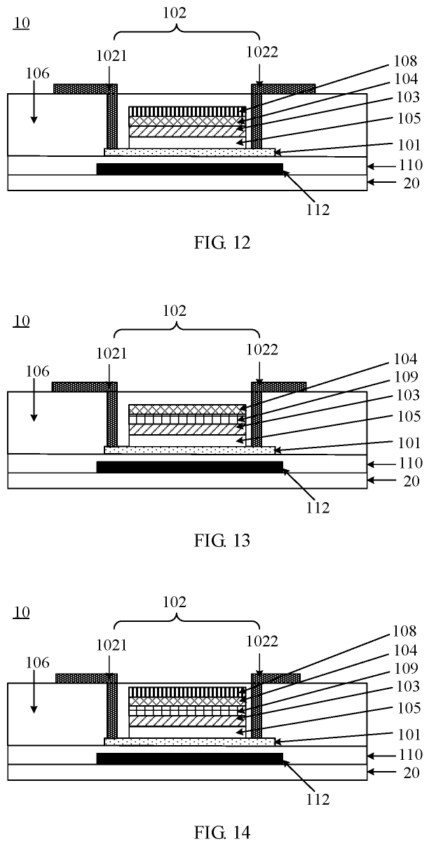

In some embodiments, referring to FIG. 12, the thin film transistor 10 merely includes the first buffer layer 108. In some embodiments, referring to FIG. 13, the thin film transistor 10) merely includes the second buffer layer 109. In some embodiments, referring to FIG. 14, the thin film transistor includes the first buffer layer 108 and the second buffer layer 109.

In some embodiments, a sheet resistance of the oxygen supplementation layer 103 is greater than a sheet resistance of the first buffer layer 108 and a sheet resistance of the second buffer layer 109. In addition, both the sheet resistance of the first buffer layer 108 and the sheet resistance of the second buffer layer 109 are greater than a sheet resistance of the second gate electrode 107.

In above embodiments, two sides of the active layer 101 are provided with film layers for blocking light. For example, in some embodiments (shown in FIGS. 5 to 9), two sides of the active layer 101 are respectively provided with the first gate electrode 104 and the second gate electrode 107. In some embodiments (shown in FIGS. 11 to 14), two sides of the active layer 101 are respectively provided with the first gate electrode 104 and the shielding layer 112. Thus, an effect of the light on the active layer is avoided, and a light stability of the thin film transistor 10 is greater.

TABLE 1

| | Threshold | Mobility | Subthreshold | Current |
|---|---|---|---|---|
| Name | (V) | (cm²/V · s) | swing | (μA) |
| Other way | −2.0 | 16 | 0.28 | 4.3 |
| Embodiments | −0.3 | 22 | 0.20 | 24.8 |
| of the present | | | | |
| disclosure | | | | |

Referring to Table 1, the threshold voltage in the technical solutions in the embodiments of the present disclosure is −0.3 V, and the threshold voltage in the technical solutions in other way is −2.0 V. That is, compared with other way, the technical solutions in the embodiments of the present disclosure improve negatively biased property. The mobility in the technical solutions in the embodiments of the present disclosure is 22 cm²/V·s, and the mobility in the technical solutions in other way is 16 cm²/V·s. That is, compared with other way, the mobility in the technical solutions in the embodiments of the present disclosure is greater. The subthreshold swing (SS) in the technical solutions in the embodiments of the present disclosure is 0.20, and the subthreshold swing in the technical solutions in other way is 0.28. That is, compared with other way, the subthreshold swing in the technical solutions in the embodiments of the present disclosure is less. The current in the technical solutions in the embodiments of the present disclosure is 4.3 μA, and the current in the technical solutions in other way is 24.8 μA. That is, compared with other way, the current in the technical solutions in the embodiments of the present disclosure is greater. The subthreshold swing represents a property metric of switching rate of the thin film transistor between an open state and a closed state, and is used to represent an increased rate of the current passing through the thin film transistor in the open state.

In addition, it is acquired from Table 1 that, in the technical solutions in the embodiments of the present disclosure, by disposing the film layers for blocking light on the two sides of the active layer, the negatively biased property and the mobility is improved, the subthreshold swing is reduced, and the property of the thin film transistor is greater.

In summary, a thin film transistor is provided in the embodiments of the present disclosure. The thin film transistor includes an active layer, source and drain electrodes, and an oxygen supplementation layer. As an orthogonal projection of the oxygen supplementation layer on the base substrate is at least partially overlapped with an orthogonal projection of a target portion of the active layer on the base substrate, oxygen introduced in forming the oxygen supplementation layer in the thin film transistor is capable of diffusing to the target portion of the active layer, such that a defect in the target portion of the active layer is reduced, and the property of the thin film transistor is greater.

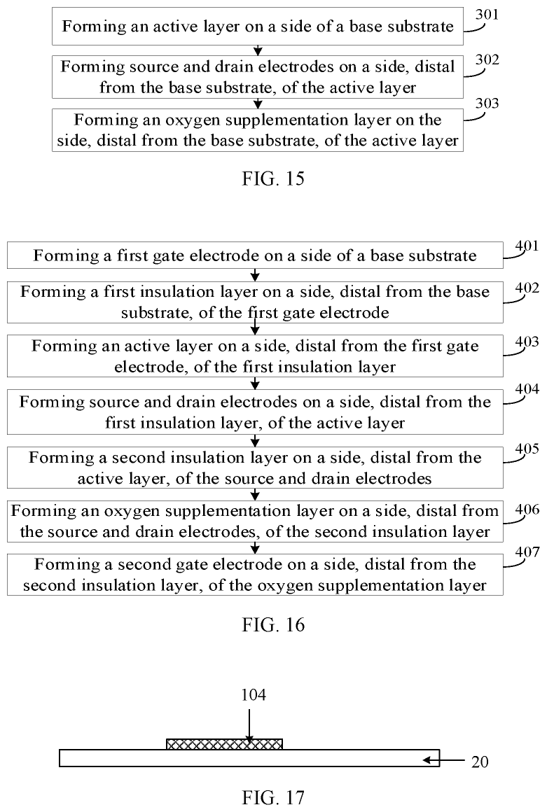

FIG. 15 is a flowchart of a method for manufacturing a thin film transistor according to some embodiments of the present disclosure. The method is applicable to manufacturing the thin film transistor 10 in above embodiments. Referring to FIG. 15, it is acquired that the method includes the following steps.

In S301, an active layer is formed on a side of the base substrate.

In the embodiments of the present disclosure, an active layer thin film is formed on the side of the base substrate, and the active layer is formed by patterning the active layer thin film. In some embodiments, the patterning process includes photo resist (PR) coating, exposing, developing, etching, photo resist removing, and the like.

In S302, source and drain electrodes are formed on a side, distal from the base substrate, of the active layer.

In the embodiments of the present disclosure, source and drain electrodes metal thin films are formed on the side, distal from the base substrate, of the active layer, and the source and drain electrodes are formed by patterning the source and drain electrodes metal thin films. In some embodiments, the patterning process includes etching the source and drain electrodes metal thin films by an etchant. The source and drain electrodes include a source electrode and a drain electrode, and the source electrode and the drain electrode are connected to the active layer.

In S303, an oxygen supplementation layer is formed on the side, distal from the base substrate, of the active layer.

In the embodiments of the present disclosure, a metal oxide thin film is formed on the side, distal from the base substrate 20, of the active layer 101, and the oxygen supplementation layer 103 is formed by patterning the metal oxide thin film. An orthogonal projection of the oxygen supplementation layer 103 on the base substrate 20 is at least partially overlapped with an orthogonal projection of a target portion 101a of the active layer 101 on the base substrate 20, and the orthogonal projection of the target portion 101a on the base substrate 20 is not overlapped with orthogonal projections of the source and drain electrodes 102 on the base substrate 20.

As the orthogonal projection of the target portion 101a of the active layer 101 on the base substrate 20 is not overlapped with the orthogonal projections of the source and drain electrodes 102 on the base substrate 20, compared with other portions of the active layer 101, the target portion 101a of the active layer 101 is prone to an effect of the etchant in forming the source and drain electrodes 102 by etching a metal material by the etchant, so as to generate defects. Thus, it is necessary to perform the oxygen supplementation on the target portion 101a to improve the defects of oxygen vacancies in the target portion 101a of the active layer 101, so as to ensure the property of the thin film transistor.

In the embodiments of the present disclosure, film layers of the thin film transistor are formed in a reaction chamber. As the oxygen supplementation layer 103 includes the metal oxide, the oxygen is introduced into the reaction chamber in depositing the metal material on the side of the base substrate 20 when the oxygen supplementation layer 103 is formed, so as to form the metal oxide thin film. In addition, as the oxygen supplementation layer 103 is disposed on the side, distal from the base substrate 20, of the active layer 101, the active layer 101 is formed prior to the oxygen supplementation layer 103. In the case that the orthogonal projection of the oxygen supplementation layer 103 on the base substrate 20 is at least partially overlapped with the orthogonal projection of the target portion 101a of the active layer 101 on the base substrate 20, oxygen introduced in forming the oxygen supplementation layer 103 is capable of diffusing to the target portion 101a of the active layer 101, such that the defects of oxygen vacancies in the target portion 101a of the active layer 101 is reduced, and the property of the thin film transistor 10 is greater.

In summary, a method for manufacturing a thin film transistor is provided in the embodiments of the present disclosure. The acquired thin film transistor includes an active layer, source and drain electrodes, and an oxygen supplementation layer. As an orthogonal projection of the oxygen supplementation layer on the base substrate is at least partially overlapped with an orthogonal projection of a target portion of the active layer on the base substrate, oxygen introduced in forming the oxygen supplementation layer in the thin film transistor is capable of diffusing to the target portion of the active layer, such that a defect in the target portion of the active layer is reduced, and the property of the thin film transistor is greater.

FIG. 16 is a flowchart of another method for manufacturing a thin film transistor according to some embodiments of the present disclosure. The method is applicable to manufacturing the thin film transistor 10 in FIG. 5. Referring to FIG. 16, it is acquired that the method includes the following steps.

In S401, a first gate electrode is formed on a side of the base substrate.

In the embodiments of the present disclosure, referring to FIG. 17, a first gate electrode thin film is formed on the side of the base substrate by sputter deposition, and the first gate electrode is formed by patterning the first gate electrode thin film. In some embodiments, the patterning process includes photo resist coating, exposing, developing, etching, photo resist removing, and the like.

In some embodiments, the deposition is one of: physical vapour deposition (PVD), pulsed laser deposition (PLD), and metal organic chemical vapor deposition (MOCVD).

In S402, an active layer is formed on a side, distal from the base substrate, of the first gate electrode.

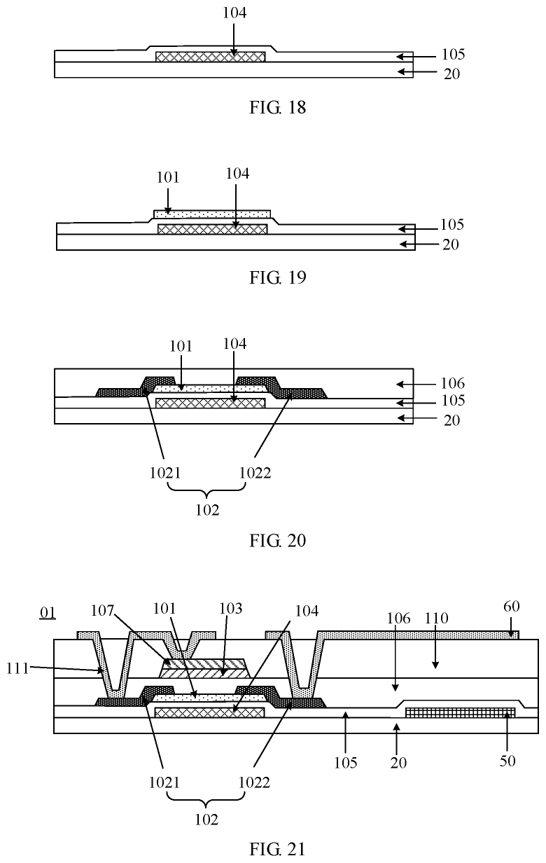

In the embodiments of the present disclosure, referring to FIG. 18, a first insulation layer is formed on the side, distal from the base substrate, of the first gate electrode by chemical vapor deposition (CVD).

In S403, an active layer is formed on a side, distal from the first gate electrode, of the first insulation layer.

In the embodiments of the present disclosure, referring to FIG. 19, an active layer thin film is formed on the side of the base substrate 20, and the active layer 101 is formed by patterning the active layer thin film.

In S404, source and drain electrodes are formed on a side, distal from the first insulation layer, of the active layer.

In the embodiments of the present disclosure, referring to FIG. 20, source and drain electrodes metal thin films is formed on the side of the active layer 101 by sputter deposition, and the source and drain electrodes are formed by patterning the source and drain electrodes metal thin films.

In some embodiments, the deposition is one of: PVD, PLD, and MOCVD.

In S405, a second insulation layer is formed on a side, distal from the active layer, of the source and drain electrodes.

In the embodiments of the present disclosure, referring to FIG. 20, the second insulation layer 106 is formed on the side, distal from the active layer 101, of the source and drain electrodes 102 by CVD.

In S406, an oxygen supplementation layer is formed on a side, distal from the source and drain electrodes, of the second insulation layer.

In the embodiments of the present disclosure, referring to FIG. 5, a metal oxide thin film is formed on the side, distal from the source and drain electrodes 102, of the second insulation layer 106, and the oxygen supplementation layer is formed by patterning the metal oxide thin film.

A metal material is deposited on the side, distal from the source and drain electrodes, of the second insulation layer 106 in forming the metal oxide thin film, and the oxygen is introduced into a reaction chamber in depositing the metal material, so as to form the metal oxide thin film.

In addition, the active layer 101 is formed prior to the oxygen supplementation layer 103, oxygen introduced into the reaction chamber in forming the oxygen supplementation layer 103 is capable of diffusing to the target portion 101a of the active layer 101, such that the defects in the target portion 101a of the active layer 101 is reduced, and the property of the thin film transistor 10 is greater.

In some embodiments, the reaction chamber is merely introduced with the oxygen in forming the metal oxide thin film of the oxygen supplementation layer 103. In some embodiments, the reaction chamber is introduced with other gas than the oxygen, such as Ar, which is not limited in the embodiments of the present disclosure.

In S407, a second gate electrode is formed on a side, distal from the second insulation layer, of the oxygen supplementation layer.

In the embodiments of the present disclosure, referring to FIG. 5, a second gate electrode thin film is formed on the side of the oxygen supplementation layer by sputter deposition, and the second gate electrode is formed by patterning the second gate electrode thin film.

In some embodiments, the deposition is one of: PVD, PLD, and MOCVD.

In summary, a method for manufacturing a thin film transistor is provided in the embodiments of the present disclosure. The acquired thin film transistor includes an active layer, source and drain electrodes, and an oxygen supplementation layer. As an orthogonal projection of the oxygen supplementation layer on the base substrate is at least partially overlapped with an orthogonal projection of a target portion of the active layer on the base substrate, oxygen introduced in forming the oxygen supplementation layer in the thin film transistor is capable of diffusing to the target portion of the active layer, such that a defect in the target portion of the active layer is reduced, and the property of the thin film transistor is greater.

In the embodiments of the present disclosure, the method for manufacturing any one of thin film transistors in FIGS. 3 to 14 is referred to the manufacturing method in above embodiments, which is not repeated herein.

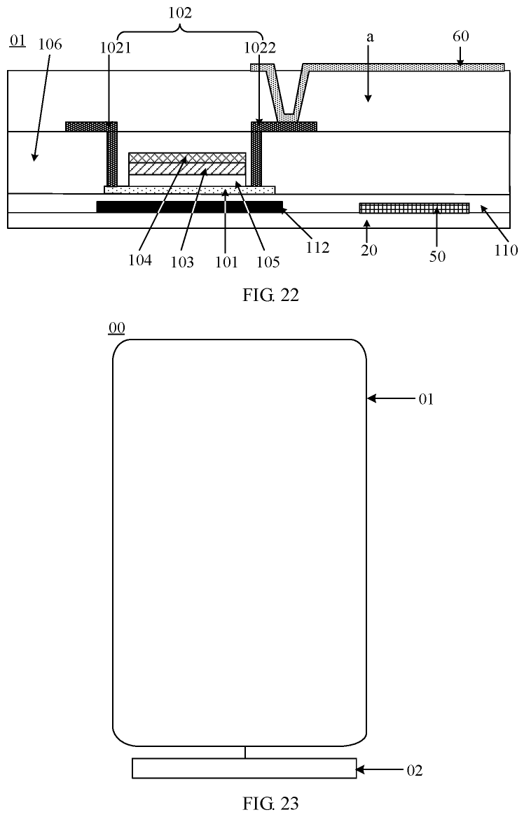

FIG. 21 is a schematic structural diagram of a display panel according to some embodiments of the present disclosure, and FIG. 22 is a schematic structural diagram of another display panel according to some embodiments of the present disclosure. Referring to FIG. 21 and FIG. 22, the display panel 01 includes a base substrate 20 and the thin film transistor 10, in above embodiments, disposed on the base substrate 20. In some embodiments, the thin film transistor in FIG. 21 is the thin film transistor 10 in FIG. 9. The thin film transistor in FIG. 22 is the thin film transistor 10 in FIG. 11.

Referring to FIG. 21 and FIG. 22, the display panel 01 further includes a pixel electrode 50 and a common electrode 60. The common electrode 60 is connected to the drain electrode 1022 via a via hole. An orthogonal projection of the pixel electrode 50 on the base substrate is not overlapped with an orthogonal projection of the active layer 101 in the thin film transistor 10 on the base substrate 20.

In some embodiments, the pixel electrode 50 and the common electrode 60 are manufactured by transparent materials, such as ITO.

Referring to FIG. 21, in manufacturing the display panel 01, the pixel electrode 50 is formed on the base substrate 20, and then the first gate electrode 104, the first insulation layer 105, the active layer 101, the source and drain electrodes 102, the second insulation layer 106, the oxygen supplementation layer 103, the second gate electrode 107, the third insulation layer 110, the connection electrode 111, and the common electrode 60 are sequentially formed. The common electrode 60 and the connection electrode 111 are formed by one patterning process.

Referring to FIG. 21, in manufacturing the display panel 01, the pixel electrode 50 is formed on the base substrate 20, and the shielding layer 112, the third insulation layer 110, the active layer 101, the first insulation layer 105, the oxygen supplementation layer 103, the first gate electrode 104, the second insulation layer 106, and the source and drain electrodes 102 are sequentially formed. Then, an inter-layer dielectric (ILD) a is formed on a side, distal from the base substrate 20, of the source and drain electrodes 102, and eventually, the common electrode 60 is formed on a side, distal from the base substrate 20, of the inter-laver dielectric a.

In some embodiments, positions of the pixel electrode 50 and the common electrode 60 are changeable. That is, the common electrode 60 is disposed on a side of the base substrate, and the pixel electrode 50 is disposed on a side, distal from the base substrate 20, of the third insulation layer 110, and is connected to the drain electrode 1022 via the via hole.

In summary, a display panel is provided in the embodiments of the present disclosure. A thin film transistor in the display panel includes an active layer, source and drain electrodes, and an oxygen supplementation layer. As an orthogonal projection of the oxygen supplementation layer on the base substrate is at least partially overlapped with an orthogonal projection of a target portion of the active layer on the base substrate, oxygen introduced in forming the oxygen supplementation layer in the thin film transistor is capable of diffusing to the target portion of the active layer, such that a defect in the target portion of the active layer is reduced, and the property of the thin film transistor is greater.

FIG. 23 is a schematic structural diagram of a display device according to some embodiments of the present disclosure. Referring to FIG. 23, it is acquired that the display device 00 includes a power supply 02 and the display panel 01 in above embodiments. The power supply 02 is configured to supply power for the display panel 01.

In some embodiments, the display device is any products or parts with a display function, such as an organic light-emitting diode (OLED) display device, a liquid crystal display, electronic paper, a mobile phone, a tablet computer, a television, a display, a notebook computer, a digital photo frame, a navigator, and the like.

An x-ray detector is further provided in the embodiments of the present disclosure. The x-ray detector includes the thin film transistor in FIGS. 3 to 14. The x-ray detector includes a substrate, a plurality of detection units on the substrate, and a scintillator layer on the plurality of detection units. Each of the plurality of detection units includes the thin film transistor and a photosensitive structure. The photosensitive structure is disposed on the drain electrode of the thin film transistor, and is electronically connected to the thin film transistor. The scintillator layer is configured to convert the x-ray to visible light, the photosensitive structure is configured to convert the visible light to an electrical signal, and the thin film transistor acts as a switch for reading the electrical signal.

Described above are example embodiments of the present disclosure, and are not intended to limit the present disclosure. Any modifications, equivalent replacements, improvements and the like made within the spirit and principles of the present disclosure are included within the scope of protection of the present disclosure.

1. A thin film transistor, comprising:
an active layer disposed on a side of a base substrate;
source and drain electrodes disposed on a side, distal from the base substrate, of the active layer; and
an oxygen supplementation layer disposed on the side, distal from the base substrate, of the active layer and containing a metal oxide, wherein an orthogonal projection of the oxygen supplementation layer on the base substrate is at least partially overlapped with an orthogonal projection of a target portion of the active layer on the base substrate, and the orthogonal projection of the target portion on the base substrate is not overlapped with orthogonal projections of the source and drain electrodes on the base substrate.

2. The thin film transistor according to claim 1, wherein the orthogonal projection of the oxygen supplementation layer on the base substrate covers the orthogonal projection of the target portion on the base substrate.

3. The thin film transistor according to claim 1, further comprising: a first gate electrode, a first insulation layer, and a second insulation layer; wherein the first gate electrode, the first insulation layer, the active layer, the source and drain electrodes, the second insulation layer, and the oxygen supplementation layer are sequentially laminated in a direction away from the base substrate.

4. The thin film transistor according to claim 3, further comprising: a second gate electrode; wherein the second gate electrode is disposed on a side, distal from the base substrate, of the oxygen supplementation layer, and an orthogonal projection of the second gate electrode on the base substrate is at least partially overlapped with the orthogonal projection of the target portion on the base substrate.

5. The thin film transistor according to claim 4, further comprising: at least one of a first buffer layer and a second buffer layer; wherein
the first buffer layer is disposed on a side, distal from the oxygen supplementation layer, of the second gate electrode; and
the second buffer layer is disposed between the second gate electrode and the oxygen supplementation layer.

6. The thin film transistor according to claim 4, further comprising: a third insulation layer and a connection electrode; wherein
the third insulation layer is disposed on a side, distal from the base substrate, of the second gate electrode, the connection electrode is disposed on a side, distal from the base substrate, of the third insulation layer, and the second gate electrode is electrically connected to the source and drain electrodes or the first gate electrode by the connection electrode.

7. The thin film transistor according to claim 1, further comprising: a first gate electrode, a first insulation layer, and a second insulation layer; wherein the active layer, the first insulation layer, the oxygen supplementation layer, the first gate electrode, the second insulation layer, and the source and drain electrodes are sequentially laminated in a direction away from the base substrate.

8. The thin film transistor according to claim 7, further comprising: a shielding layer and a third insulation layer; wherein
the shielding layer is disposed on a side, proximal to the base substrate, of the active layer, the third insulation layer is disposed between the shielding layer and the active layer, and an orthogonal projection of the shielding layer on the base substrate covers an orthogonal projection of the active layer on the base substrate.

9. The thin film transistor according to claim 7, further comprising: at least one of a first buffer layer and a second buffer layer; wherein
the first buffer layer is disposed on a side, distal from the oxygen supplementation layer, of the first gate electrode; and
the second buffer layer is disposed between the first gate electrode and the oxygen supplementation layer.

10. The thin film transistor according to claim 1, wherein
a material of the active layer comprises at least one of: an indium-gallium-zinc oxide, an indium-gallium-zinc-tin oxide, an indium-tin oxide, an indium-zinc oxide, and an indium-tin-zinc oxide; and
a material of the oxygen supplementation layer comprises at least one of: an indium-gallium-zinc oxide, an indium-gallium-zinc-tin oxide, an indium-tin oxide, an indium-zinc oxide, an indium-tin-zinc oxide, a molybdenum oxide, an aluminum oxide, a copper oxide, an indium oxide, a tin oxide, a zinc oxide, and a nickel oxide.

11. A method for manufacturing a thin film transistor, comprising: forming an active layer, source and drain electrodes, and an oxygen supplementation layer on a side of the base substrate; wherein
the source and drain electrodes are disposed on a side, distal from the base substrate, of the active layer; and
the oxygen supplementation layer is disposed on the side, distal from the base substrate, of the active layer, and contains a metal oxide, an orthogonal projection of the oxygen supplementation layer on the base substrate is at least partially overlapped with an orthogonal projection of a target portion of the active layer on the base substrate, and the orthogonal projection of the target portion on the base substrate is not overlapped with orthogonal projections of the source and drain electrodes on the base substrate.

12. The method according to claim 11, wherein forming the oxygen supplementation layer on the side of the base substrate comprises:
forming a metal oxide thin film on the side, distal from the base substrate, of the active layer by introducing oxygen into a reaction chamber in depositing a metal material on the side of the base substrate; and
forming the oxygen supplementation layer by patterning the metal oxide thin film;
wherein the oxygen is diffusible to the target portion in introducing the oxygen into the reaction chamber.

13. A display panel, comprising: a base substrate, and a thin film transistor disposed on the base substrate; wherein the thin film transistor comprises:
an active layer disposed on a side of the base substrate;
source and drain electrodes disposed on a side, distal from the base substrate, of the active layer; and
an oxygen supplementation layer disposed on the side, distal from the base substrate, of the active layer and containing a metal oxide, wherein an orthogonal projection of the oxygen supplementation layer on the base substrate is at least partially overlapped with an orthogonal projection of a target portion of the active layer on the base substrate, and the orthogonal projection of the target portion on the base substrate is not overlapped with orthogonal projections of the source and drain electrodes on the base substrate.

14. A display device, comprising: a power supply, and the display panel as defined in claim 13; wherein the power supply is configured to supply power to the display panel.

15. The display panel according to claim 13, wherein the orthogonal projection of the oxygen supplementation layer on the base substrate covers the orthogonal projection of the target portion on the base substrate.

16. The display panel according to claim 13, further comprising: a first gate electrode, a first insulation layer, and a second insulation layer; wherein the first gate electrode, the first insulation layer, the active layer, the source and drain electrodes, the second insulation layer, and the oxygen supplementation layer are sequentially laminated in a direction away from the base substrate.

17. The display panel according to claim 16, further comprising: a second gate electrode; wherein the second gate electrode is disposed on a side, distal from the base substrate, of the oxygen supplementation layer, and an orthogonal projection of the second gate electrode on the base substrate is at least partially overlapped with the orthogonal projection of the target portion on the base substrate.

18. The display panel according to claim 17, further comprising: at least one of a first buffer layer and a second buffer layer; wherein
the first buffer layer is disposed on a side, distal from the oxygen supplementation layer, of the second gate electrode; and
the second buffer layer is disposed between the second gate electrode and the oxygen supplementation layer.

19. The display panel according to claim 17, further comprising: a third insulation layer and a connection electrode; wherein
the third insulation layer is disposed on a side, distal from the base substrate, of the second gate electrode, the connection electrode is disposed on a side, distal from the base substrate, of the third insulation layer, and the second gate electrode is electrically connected to the source and drain electrodes or the first gate electrode by the connection electrode.

20. The display panel according to claim 13, further comprising: a first gate electrode, a first insulation layer, and a second insulation layer; wherein the active layer, the first insulation layer, the oxygen supplementation layer, the first gate electrode, the second insulation layer, and the source and drain electrodes are sequentially laminated in a direction away from the base substrate.
